(19) United States
(12) Patent Application Publication
(10) Pub. No.: US 2025/0022928 A1
(43) Pub. Date: Jan. 16, 2025

(54) CONTACT STRUCTURE FOR III-NITRIDE TRANSISTORS WITH CAP LAYERS

(71) Applicant: Finwave Semiconductor, Inc., Belmont, MA (US)

(72) Inventor: Hal Emmer, Wayland, MA (US)

(21) Appl. No.: 18/768,972

(22) Filed: Jul. 10, 2024

Related U.S. Application Data
(60) Provisional application No. 63/526,318, filed on Jul. 12, 2023.

(51) Int. Cl. H01L 29/423; H01L 23/528; H01L 29/20; H01L 29/417; H01L 29/778

(52) U.S. Cl. CPC H01L 29/42316; H01L 23/5286; H01L 29/2003; H01L 29/41758; H01L 29/7786

(57) ABSTRACT

A technique for making contact to the cap layers in multifinger III-Nitride transistors with cap layers is described. A contact structure is disposed at an end of the transistor device and connects to the cap layer of individual fingers of the transistor device using a cap contact bus. A transistor is also described that includes a contact structure that is used to move the cap layer contact away from the individual fingers. Transistors may be created using unit cells, wherein each unit cell includes a contact structure and cap contact bus.

This application claim priority to U.S. Provisional Patent Application Ser. No. 63/526, 318, filed Jul. 12, 2023, the disclosure of which is incorporated herein by reference in its entirety.

### FIELD

Embodiments of the present disclosure relate to methods for making contact to the cap layers in III-Nitride transistors.

### BACKGROUND

As described in U.S. Pat. No. 11,695,052, the disclosure of which is incorporated herein by reference in its entirety, a cap layer may be used to form the transistor gate in order to reduce the off-state capacitance between the source and drain contacts of a III-Nitride transistor and improve performance, especially at high frequencies.

However, the realization of larger devices with many fingers becomes challenging due to the need to accommodate the cap layer contact area 4. As shown in FIG. 1, these larger devices typically have alternating source contacts 1 and drain contacts 2, with the cap layer 3 disposed between adjacent contacts. If the cap layer contacts 4 are placed along each finger, outside the active region, as suggested in the previously mentioned Patent and shown in FIGS. 1 and 2, there will be additional capacitance between the cap layer contact area 4 and the source/drain metallization, impacting performance. Specifically, the cap layer contact areas 4 in these figures are located along the sides of the transistor device.

Thus, in certain embodiments, it may be beneficial to create contacts to the cap layer of a multifinger transistor device that do not adversely affect the capacitance of the transistor device.

### SUMMARY

A technique for making contact to the cap layers in multifinger III-Nitride transistors with cap layers is described. A contact structure is disposed at an end of the transistor device and connects to the cap layer of individual fingers of the transistor device using a cap contact bus. A transistor is also described that includes a contact structure that is used to move the cap layer contact away from the individual fingers. Transistors may be created using unit cells, wherein each unit cell includes a contact structure and cap contact bus.

According to one embodiment, a multifinger III-Nitride transistor device, having an active region and two ends and two sides, is disclosed. The transistor device comprises a channel layer; a barrier layer disposed on the channel layer, wherein electrons are formed at an interface between the channel layer and the barrier layer in the active region; a plurality of source contacts disposed above the channel layer, wherein the source contacts extend across the active region from one side to an opposite side; a plurality of drain contacts disposed above the channel layer extending across the active region and parallel to the source contacts; a plurality of gate regions disposed between each adjacent source contact and drain contact; a cap layer disposed in each gate region; a contact structure disposed at a first end of the multifinger III-Nitride transistor device; and a cap contact bus in electrical communication with the contact structure and with each of the cap layers, disposed along a first side of the multifinger III-Nitride transistor device. In some embodiments, the transistor device comprises a second cap contact bus disposed along a second side of the multifinger III-Nitride transistor device and in electrical communication with the contact structure and with each of the cap layers. In some embodiments, the transistor device comprises a second contact structure disposed at a second end of the multifinger III-Nitride transistor device and in electrical communication with the cap contact bus. In some embodiments, the transistor device comprises a second contact structure disposed at a second end of the multifinger III-Nitride transistor device and in electrical communication with the cap contact bus; and a second cap contact bus disposed along a second side of the multifinger III-Nitride transistor device, wherein the second cap contact bus is in electrical communication with the contact structure, the second contact structure and with each of the cap layers. In some embodiments, the contact structure and cap contact bus are connected using a via disposed in a dielectric layer. In some e embodiments, the contact structure comprises a metal structure disposed above a contact cap layer. In certain embodiments, the barrier layer is removed beneath the contact cap layer such that the contact cap layer is disposed on the channel layer. In certain embodiments, electrical properties of the barrier layer or the channel layer beneath the contact cap layer are modified such that carriers are not present in the channel layer beneath the contact structure. In some embodiments, the cap contact bus comprises a metal trace disposed above a bus cap layer.

According to another embodiment, a multifinger III-Nitride transistor device is disclosed. The transistor device comprises a plurality of unit cells; wherein each unit cell has an active region, two ends and two sides, wherein each unit cell comprises: a channel layer; a barrier layer disposed on the channel layer, wherein electrons are formed at an interface between the channel layer and the barrier layer in the active region; a plurality of source contacts disposed above the channel layer, wherein the source contacts extend across the active region from one side to an opposite side; a plurality of drain contacts disposed above the channel layer, extending across the active region and parallel to the source contacts; a plurality of gate regions disposed between each adjacent source contact and drain contact; a cap layer disposed in each gate region; a contact structure disposed at a first end of the unit cell; a second contact structure disposed at a second end of the unit cell; and a cap contact bus in electrical communication with the contact structure, the second contact structure, and with each of the cap layers, disposed along a first side of the unit cell; wherein the second contact structure of a first unit cell is adjacent to the contact structure of a second unit cell and is electrically coupled together and to a common gate signal, and wherein the plurality of source contacts in each unit cell are electrically coupled to a common source signal and the plurality of drain contacts in each unit cell are electrically coupled to a common drain signal. In some embodiments, a second cap contact bus is disposed along a second side of each unit cell and is in electrical communication with the contact structure, the second contact structure, and with each of the cap layers in the unit cell. In some embodiments, the plurality of unit cells each have a same configuration. In some embodiments, at least one of the plurality of unit cells has a configuration different than another of the plurality of unit cells.

According to another embodiment, a multifinger III-Nitride transistor device, having an active region and two ends and two sides, is disclosed. The transistor device comprises a channel layer; a barrier layer disposed on the channel layer, wherein electrons are formed at an interface between the channel layer and the barrier layer in the active region; a plurality of source contacts disposed above the channel layer, wherein the source contacts extend across the active region from one side to an opposite side; a plurality of drain contacts disposed above the channel layer, extending across the active region and parallel to the source contacts; a plurality of gate regions disposed between each adjacent source contact and drain contact; a cap layer from a first set of cap layers disposed in each gate region; a cap layer from a second set of cap layers disposed in each gate region; a first contact structure disposed at a first end of the multifinger III-Nitride transistor device; a second contact structure disposed at an end of the device; a first cap contact bus in electrical communication with the first contact structure and with the first set of cap layers, disposed along a first side of the device; and a second cap contact bus in electrical communication with the second contact structure and with the second set of cap layers, disposed along a second side of the device. In some embodiments, a third contact structure is disposed at a second end of the multifinger III-Nitride transistor device and is in electrical communication with the first cap contact bus. In some embodiments, the second contact structure is disposed at the first end of the multifinger III-Nitride transistor device. In certain embodiments, a third contact structure is disposed at a second end of the multifinger III-Nitride transistor device and is in electrical communication with the first cap contact bus and a fourth contact structure is disposed at the second end of the multifinger III-Nitride transistor device and is in electrical communication with the second cap contact bus.

### BRIEF DESCRIPTION OF THE FIGURES

For a better understanding of the present disclosure, reference is made to the accompanying drawings, which are incorporated herein by reference and in which:

FIG. 1 shows drawing of multifinger transistor with a cap contact on each finger according to the prior art;

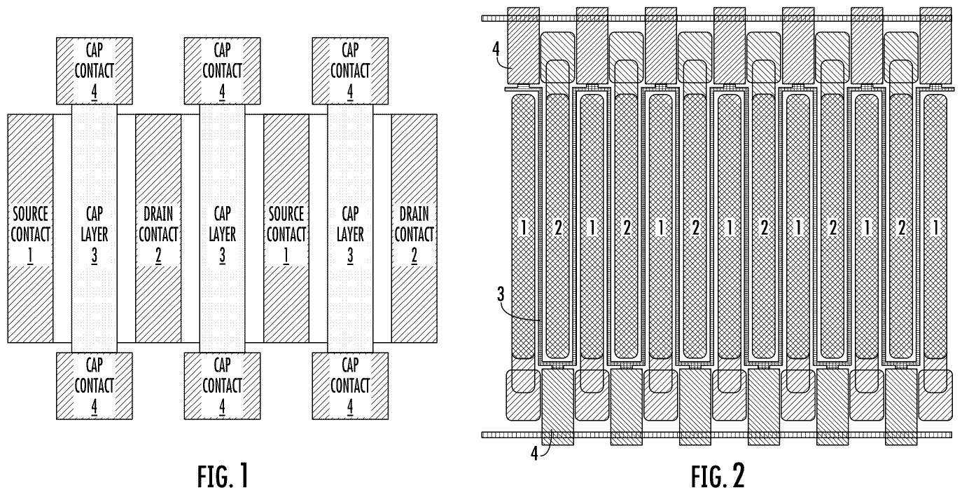

FIG. 2 shows the layout of transistor with cap layer contact at each finger according to the prior art;

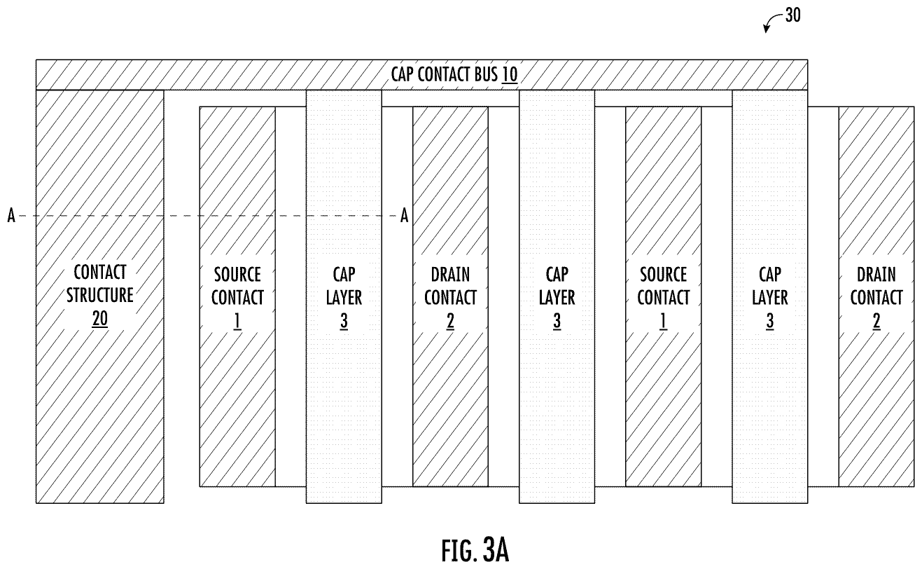

FIG. 3A shows the transistor device with the new structure according to one embodiment;

FIGS. 3B-3C show the cross-section of the transistor device of FIG. 3A taken along line A-A according to two embodiments;

FIG. 4 shows the transistor device with the new structure according to another embodiment;

FIG. 5 shows the layout of transistor with the new structure according to another embodiment;

FIGS. 6A-6B show transistor devices formed using unit cells according to two embodiments;

FIGS. 7A-7B show transistor devices formed using differently sized unit cells according to two embodiments; and

FIGS. 8A-8B show transistor devices formed with multiple cap layers between adjacent source and drain contacts.

### DETAILED DESCRIPTION

A multifinger III-Nitride transistor device is formed by having a plurality of alternating source contacts and drain contacts, where all of the source contacts are in electrical contact with a common signal. Similarly, all of the drain contacts are in electric contact with a second common signal. Gate regions are formed between each pair of adjacent source and drain contacts. Again, all of the gate regions are connected to a common gate signal. The use of multiple source contacts, drain contacts and gate regions increases the current capability of the device. A cap layer may be disposed over each gate region.

This disclosure describes a multifinger transistor device having an additional contact structure which is added to the device for the purpose of making contact to the cap layers on multiple fingers. This contact structure may be placed farther away from the source and drain fingers than is traditionally done, thereby minimizing the capacitance to the source and drain regions. The contact structure is then connected to the cap layer through a cap contact bus.

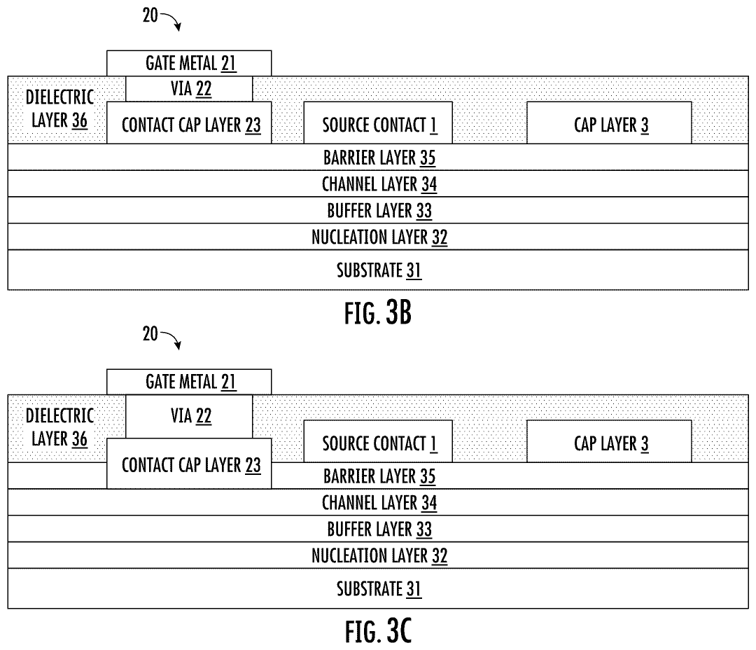

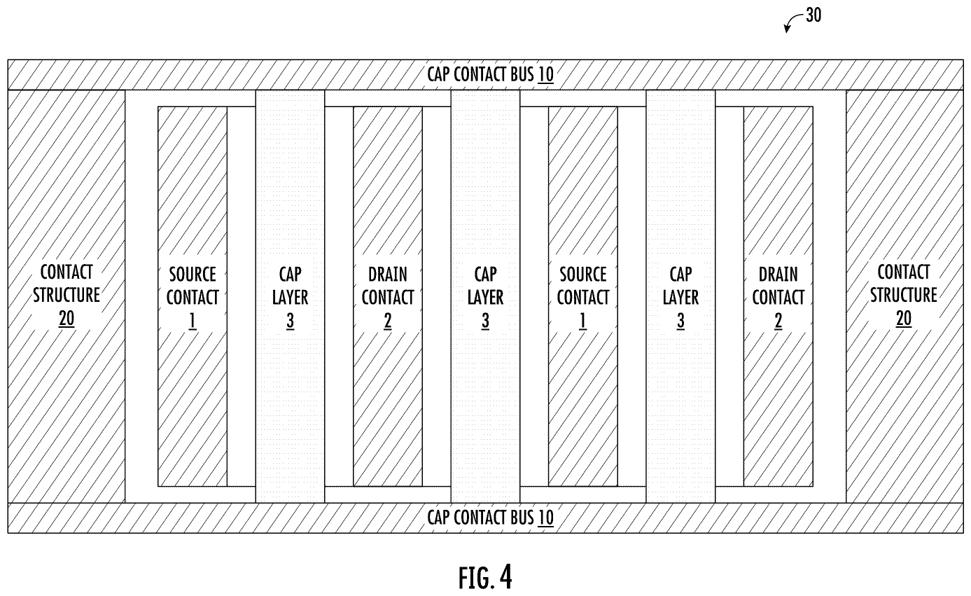

FIG. 3A shows a first embodiment of this structure. As described above, the transistor device 30 may be a multifinger device, having a plurality of source contacts 1 and drain contacts 2 disposed in the active region of the device. The source and drain contacts extend across the active region from one side to an opposite side. Cap layers 3 are disposed between adjacent source contacts 1 and drain contacts 2, each on top of a respective gate region. Each cap layer 3 forms part of a gate region of the transistor device 30. The region between adjacent source and drain contacts may be referred to as a finger or a gate region, as these terms are interchangable. The cap layer 3 is part of each finger. A contact structure 20 is disposed outside the active region of the transistor device, such as at one end of the transistor. In this disclosure, the ends of the transistor device are defined as those edges that are parallel to the longer direction of the source contact 1 and drain contact 2. In the accompanying figures, the ends of the transistor device 30 are located on the left and right sides of the device. The sides of the transistor device are defined as those edges that are perpendicular to the longer direction of the source contact 1 and drain contact 2. In the accompanying figures, the side of the transistor device 30 are located on the top and bottom sides of the device.

FIG. 3B shows a cross section of FIG. 3A along line A-A. The transistor device 30 comprises a substrate 31, which may be made of Si, SiC, Sapphire, III-nitride semiconductor, silicon-on-insulator, silicon-on-sapphire or any other suitable material or combination of materials.

In the case that the transistor device 30 is fabricated on an epitaxial layer grown on a substrate 31, a nucleation layer 32 and buffer layer 33 may be present. Thus, in some embodiments, the transistor device 30 may include a nucleation layer 32, formed on the substrate 31. The nucleation layer 32 may include AlN.

A buffer layer 33 is formed over the nucleation layer 32. The buffer layer 33 may have a thickness between 0.5 nm and several microns. The buffer 33 layer may comprise III-nitride semiconductors including GaN, AlGaN, InGaN, InAlN, InAlGaN and AlN.

A channel layer 34 is formed over the buffer layer 33. The channel layer 34 comprises a semiconductor material selected from GaAs, InGaAs, GaN, or any other suitable semiconductor material or combination of materials.

Carriers, which may be free electrons, exist in the channel layer 34 to conduct electrical current between the drain contact 2 and the source contact 1.

The channel layer 34 may comprise a single layer such as a GaN layer, or multiple layers. In one example, the channel layer 34 comprises a back-barrier structure, such as a GaN layer over an AlGaN layer (GaN/AlGaN) or a GaN layer over an InGaN layer and another GaN layer (GaN/InGaN/GaN). In another example, the channel layer 34 has a superlattice structure formed by repeating a bi-layer structure of AlGaN/GaN or AlN/GaN. The thickness of the channel layer 34 may be 5 nm, although other thicknesses may be used. The thickness of the buffer layer 33 may be between zero and a few microns, although other thicknesses are within the scope of the disclosure.

A barrier layer 35 is formed over the channel layer 34. The barrier layer 35 may be made of III-nitride semiconductors selected from AlGaN, InAlN, AlN or InAlGaN. The barrier layer 35 may be un-doped, doped with Si or doped with Mg or other impurities.

The source contact 1 and the drain contact 2 are formed above the channel layer 34 and may make electrical contact with the channel layer 34. The source contact 1 and drain contact 2 may be formed on the surface of the barrier layer 35, as shown in FIG. 3B, within the barrier layer 35, on the surface of the channel layer 34, or within the channel layer 34. Alternatively, the source and drain regions may be further recessed and make contact to the channel layer 34 through the sides of the recess.

The cap layer 3 is formed over the barrier layer 35 for each finger, in the region between the source contact 1 and the drain contact 2. In some embodiments, the cap layer 3 does not make contact with the source contact 1 and the drain contact 2. The cap layer 3 may be made of a conductive material such as a doped or undoped semiconductor material, polycrystalline material, conductive oxide or nitride, metal or any other suitable material or combination of suitable materials. The cap layer material is selected such that the gate to drain and/or gate to source capacitance in off-state is smaller at high frequencies (for example, over 10 MHz) than at low frequencies (less than 10 Hz). In one embodiment, the cap layer 3 is a Mg-doped p-type III-nitride semiconductor layer (i.e., p-type GaN) having a thickness ranging from 10 nm to more than 200 nm and Mg doping density ranging from 1E17/cm³ to more than 5E19/cm³.

A dielectric layer 36 may be disposed on top of the cap layer 3, the source contract 1 and the drain contact 2.

As shown in FIG. 3B, the contact structure 20 comprises a metal structure 21 disposed on the top layer that makes electrical contact to the contact cap layer 23 through one or more vias 22 or contacts etched through the dielectric layer 36. The contact cap layer 23 may be made of the same material as the cap layer 3, as described above. The barrier layer 35 under the contact cap layer 23 in the region of the contact structure 20 may be identical to the barrier layer 35 in the transistor region, or may be thinner. Additionally, ion implantation, diffusion, or another technique may be used to remove the electrons normally present at the interface of the barrier layer 35 and channel layer 34 in the region under the contact structure 20.

In another embodiment, shown in FIG. 3C, the barrier layer 35 under the contact structure 20 is completely removed, so that the contact cap layer 23 is disposed directly on the channel layer 34.

Thus, in these embodiments, the contact structure comprises a metal structure 21 that is disposed above the contact cap layer 23. In some embodiments, a dielectric layer 36 is disposed between the metal structure 21 and the contact cap layer 23 such that vias 22 are used to electrically connect the metal structure 21 to the contact cap layer 23. Further, in certain embodiments, the carriers that are typically disposed in the channel layer 34 are not present beneath the contact cap layer 23 under the contact structure 20. As described above, this may be achieved by removing the barrier layer 35 or by using ion implantation, diffusion, or another technique to modify the electrical properties of the barrier layer 35 or channel layer 34 such that carriers are not present in the channel layer 34 beneath the contact structure 20. In other embodiments, carriers may be present in the channel layer 34 beneath the contact structure 20.

The size of the contact structure 20 or contact structures 20 is determined by the physical and electronic properties of the cap layer 3 and the requirements for the transistor device, such as switching speed. In certain embodiments, the area of the contact structure 20 may likely be in the range of 0.1× to 10× the physical area of the cap layer 3 that forms the transistor gate. Additionally, the contact structure 20 may be between 50 nm and 5 μm thick, although other dimensions are possible.

Like the contact structure 20, the cap contact bus 10 comprises a metal material, in the form of a metal trace that is disposed on top of a bus cap layer. The cap contact bus 10 makes electrical contact to the bus cap layer through one or more vias or contacts etched through a dielectric layer. Alternatively, the metal trace may be disposed directly on the bus cap layer. The length of the cap contact bus 10 is determined by the distance between the contact structure 20 and the farthest finger in the transistor device 30. The width of the cap contact bus 10 may be less than 10 um. If the metal layer of the cap contact bus 10 is at the same level as the metal structure 21, the cap contact bus 10 and the metal structure may be directly connected. If, however, the metal layer of the cap contact bus 10 is at a lower level than the metal structure 21, vias may be used to connect the metal structure 21 to the metal layer of the cap contact bus 10. In some embodiments, the bus cap layer of the cap contact bus 10 is disposed directly on the barrier layer 35. The barrier layer 35 beneath the cap contact bus 10 may be modified so that carriers are not present in the channel layer 34 beneath the cap contact bus 10. In another embodiment, the barrier layer 35 beneath the cap contact bus 10 is not modified so that carriers are present in the channel layer 34 beneath the cap contact bus 10. Further, in some embodiments, the bus cap layer is at the same level as the cap layers 3.

Thus, any signal presented at the contact structure 20 is carried by the cap contact busses 10 to each of the plurality of cap layers 3 using vias or contacts etched into a dielectric layer.

In some embodiments, such as that shown in FIG. 3A, the metal traces that are part of the cap contact bus 10 do not extend to the fingers. Rather, the signal is carried only by the cap layer 3. In some embodiments, the metal traces may extend part of the distance across the finger. Additionally, if present, the metal traces may be narrower than the cap layer 3. In all embodiments, the metal traces consume less space than the cap layer 3 in the fingers.

In FIG. 3A, there is a single contact structure 20 located at one end of the transistor device 30. That contact structure 20 is in electrical contact with one cap contact bus 10, which is located on one side of the transistor device 30.

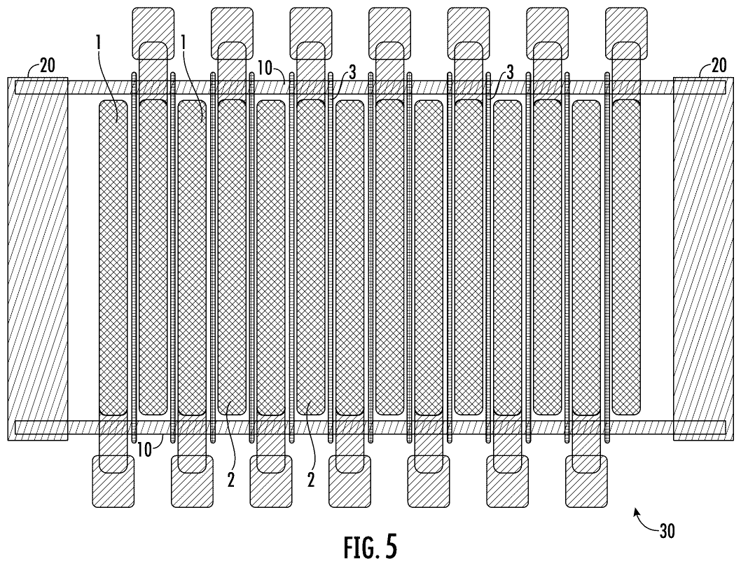

FIG. 4 shows a second embodiment, where there are multiple contact structures 20 and multiple cap contact busses 10. In this embodiment, there is a contact structure 20 disposed at each end of the transistor device 30. Similarly, there is a cap contact bus 10 disposed on each side of the transistor device 30. Each contact structure 20 is in electrical contact with both cap contact busses 10. The cross section of this embodiment is similar to that shown in FIGS. 3B-3C.

Other variations are also possible. For example, a multifinger transistor device may be formed by including only one contact structure 20 on one end of the transistor device 30 (similar to FIG. 3) and two cap contact busses 10, located on the two opposite sides of the transistor device 30 (similar to FIG. 4).

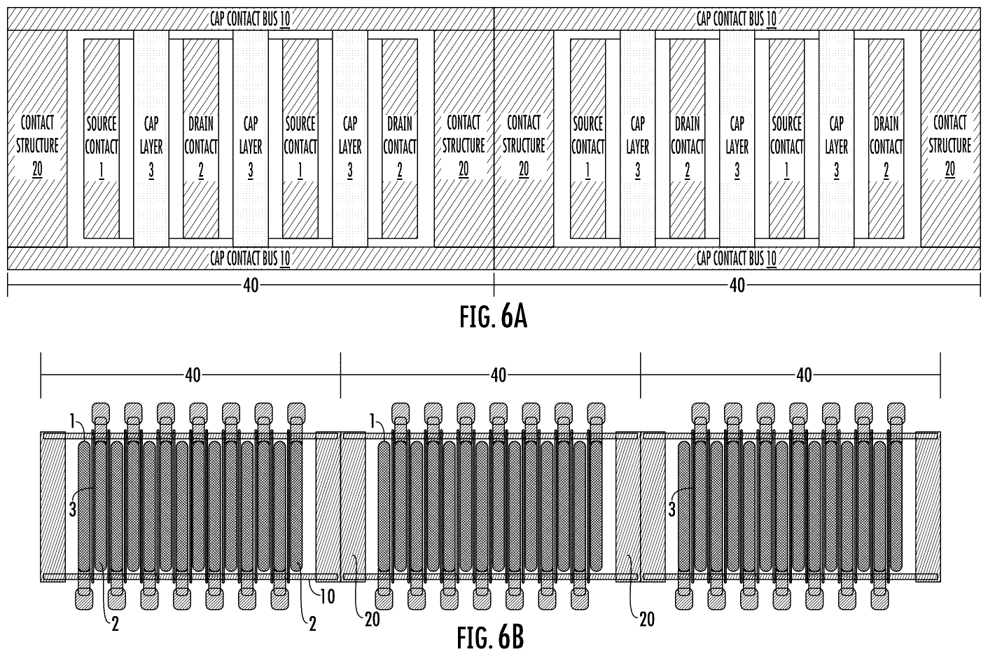

FIG. 5 shows the layout of a multifinger transistor device according to another embodiment. There are seven source contacts 1 and seven drain contacts 2. In this figure, two contact structures 20 are used for the thirteen cap layers 3.

Thus, FIG. 3-5 show a multifinger III-Nitride transistor device 30 that includes one or more contact structures 20 disposed on one or both ends of the device, and one or more cap contact busses 10 disposed along one or both sides of the device. The contact structures 20 are as shown in FIGS. 3B-3C, and the cap contact busses 10 include a metal trace disposed above a bus cap layer.

If a larger transistor is needed, more contact structures 20 may be added. For example, one or more contact structure 20 may be added in the middle of the transistor device 30, such as between a drain contact 2 and a source contact 1. This configuration may help to limit the distance between the furthest cap layers 3 and the contact structures 20.

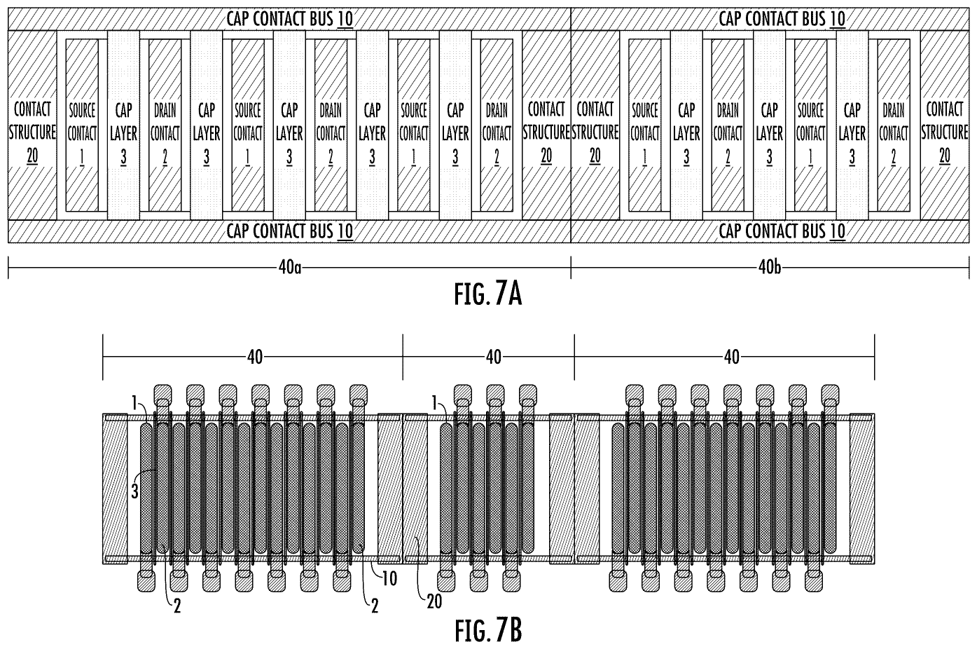

According to one embodiment, a unit cell can be formed with some number of fingers, cap layers 3, source contacts 1, and drain contacts 2. This unit cell is smaller than the total number of source and drain contacts required for the transistor device 30, and also includes one or more contact structures, and one or more cap contact busses. This unit cell may then be repeated with the contact structures 20 and cap contact busses 10 connected together to form a larger transistor, as shown in FIGS. 6A-6B. FIG. 6A shows a transistor device 30 made by coupling two unit cells 40 together. Each unit cell 40 includes two source contacts 1, two drain contacts 2, three fingers, three cap layers 3 and two cap contact busses 10 along the two opposite sides of the unit cell 40.

Additionally, there are contact structures 20 located at each end of the unit cell 40.

FIG. 6B shows the schematic of another transistor device 30 created by coupling three unit cells 40. In this figure, each unit cell includes seven source contacts 1, seven drain contacts 2, thirteen cap layers 3 and cap contact busses 10 disposed along each opposite side of the unit cell 40. Additionally, contact structures 20 are disposed on each end of the unit cell 40. The unit cell 40 used to form this device may be the circuit shown in FIG. 5, for example.

Thus, FIGS. 6A-6B show a transistor device 30 formed by coupling two or more unit cells 40 together. Each unit cell 40 includes a plurality of source contacts 1, a plurality of drain contacts 2, a plurality of cap layers 3, each cap layer disposed on a finger located between two adjacent source and drain contacts, one or more cap contact busses 10 along the sides of the unit cell 40 and one or more contact structures 20 disposed at the ends of the unit cell 40. The transistor device 30 is created by coupling all of the source contacts 1 to a common source signal, and all of the drain contacts 2 to a common drain signal. Additionally, all of the contact structures 20 are tied to a common gate signal and connect to all of the cap contact busses 10. Note that while FIGS. 6A-6B shows contact structures disposed on both ends of the unit cell 40, it is also possible that the contact structure 20 is only located on one end. Further, while FIGS. 6A-6B show the transistor device 30 being formed using a plurality of identical unit cells, other embodiments are also possible.

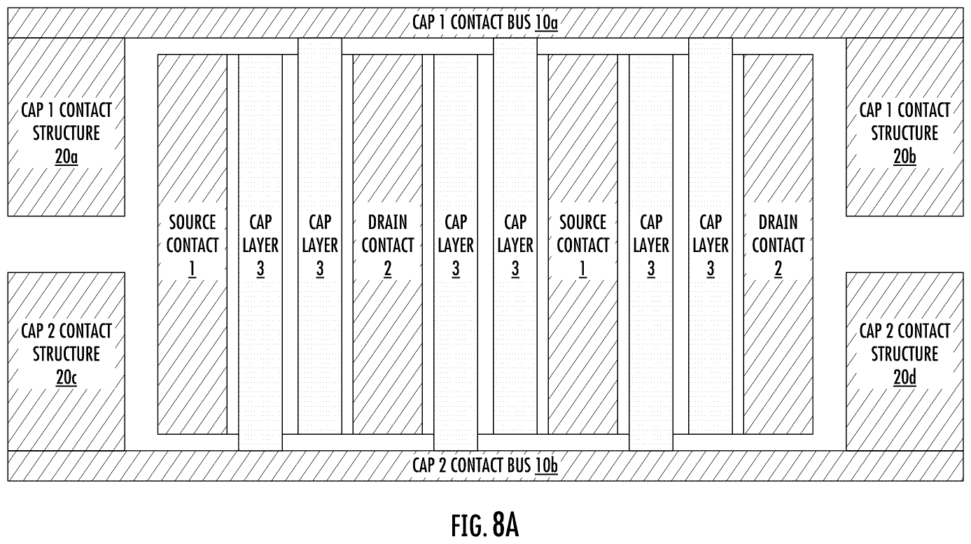

For example, the multifinger III-Nitride transistor device 30 may be formed using differently sized unit cells 40. FIG. 7A shows a transistor device 30 formed using two differently sized unit cells. The first unit cell 40a includes three source contacts, three drain contacts and five fingers with cap layers 3. The second unit cell 40b includes two source contacts, two drain contacts and three fingers with cap layers 3. As described above, each unit cell has a contact structure disposed on either end of the unit cell, and a cap contact bus disposed on either side of the unit cell. The unit cells are combined as described above to yield a device with five drain and source contacts, eight fingers with cap layers and a large contact structure disposed between an adjacent source and drain contact.

FIG. 7B shows another multifinger transistor device formed using three unit cells, where the middle unit cell is differently sized than the outer two unit cells.

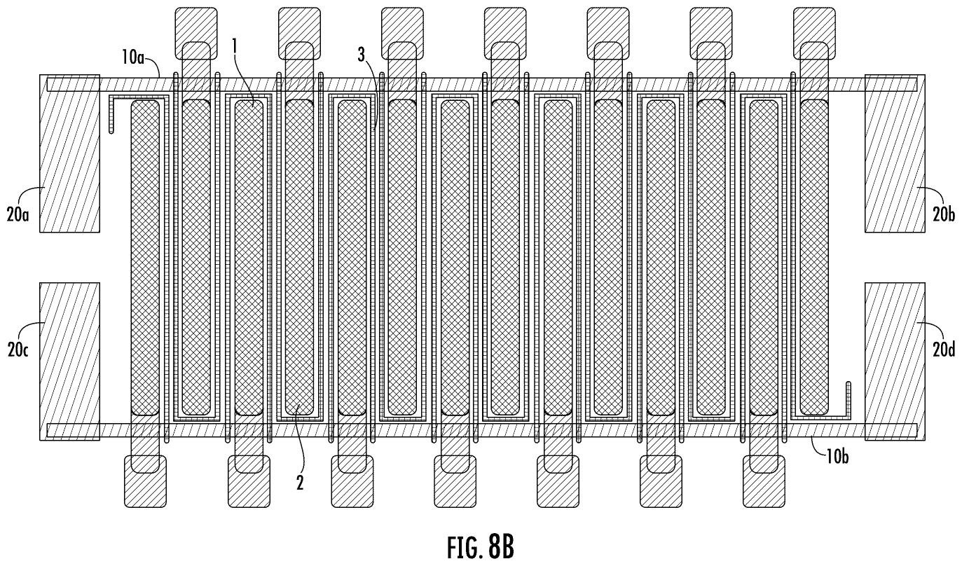

A multifinger transistor device with a finger having two or more cap layers disposed between each pair of source and drain contacts may also be realized. In this case, the transistor device comprises one or more contact structures 20 and one or more cap contact busses 10 for each cap layer 3 between each source contact 1 and drain contact 2. An example of a transistor device 30 with two cap layers 3 located in each finger disposed between each source contact 1 and drain contact 2 is shown in FIG. 8A. In this figure, there are two first contact structures 20a, 20b in electrical communication with a first cap contact bus 10a. There are also two second contact structures 20c, 20d in electrical communication with a second cap contact bus 10b. Each cap contact bus 10a, 10b is in electrical communication with a subset of the cap layers 3. Specifically, there is a first set of cap layers 3 in electrical communication with the first cap contact bus 10a, and a second set of cap layers 3 in electrical communication with the second cap contact bus 10b. Note that each finger includes one cap layer from the first set of cap layers 3 and one cap layer from the second set of cap layers 3. FIG. 8B shows an actual schematic of the device that includes multiple cap layers between adjacent source and drain contacts. Note that in other embodiments, only one contact structure may be used for each cap contact bus.

The system described herein have many advantages. By moving the cap contact structure to the end of the transistor device, the parasitic capacitance associated with the source and drain contacts may be reduced. This may improve the switching frequency of the device. Additionally, reducing the capacitance reduces the off state losses. Alternatively, the transistor device may be made larger with the same off-state loss to improve the on-state performance. This tradeoff is governed by the figure of merit Ron*Coff. Finally, switching speed is determined in part based on the contact structure area. By using larger contact structures, which are placed away from the gate, the switching speed may be increased.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A multifinger III-Nitride transistor device, having an active region and two ends and two sides, the multifinger III-Nitride transistor device comprising:
a channel layer;
a barrier layer disposed on the channel layer, wherein electrons are formed at an interface between the channel layer and the barrier layer in the active region;
a plurality of source contacts disposed above the channel layer, wherein the source contacts extend across the active region from one side to an opposite side;
a plurality of drain contacts disposed above the channel layer extending across the active region and parallel to the source contacts;
a plurality of gate regions disposed between each adjacent source contact and drain contact;
a cap layer disposed in each gate region;
a contact structure disposed at a first end of the multifinger III-Nitride transistor device; and
a cap contact bus in electrical communication with the contact structure and with each of the cap layers, disposed along a first side of the multifinger III-Nitride transistor device.

2. The multifinger III-Nitride transistor device of claim 1, further comprising:
a second cap contact bus disposed along a second side of the multifinger III-Nitride transistor device and in electrical communication with the contact structure and with each of the cap layers.

3. The multifinger III-Nitride transistor device of claim 1, further comprising:
a second contact structure disposed at a second end of the multifinger III-Nitride transistor device and in electrical communication with the cap contact bus.

4. The multifinger III-Nitride transistor device of claim 1, further comprising:
a second contact structure disposed at a second end of the multifinger III-Nitride transistor device and in electrical communication with the cap contact bus; and
a second cap contact bus disposed along a second side of the multifinger III-Nitride transistor device, wherein the second cap contact bus is in electrical communication with the contact structure, the second contact structure and with each of the cap layers.

5. The multifinger III-Nitride transistor device of claim 1, wherein the contact structure and cap contact bus are connected using a via disposed in a dielectric layer.

6. The multifinger III-Nitride transistor device of claim 1, wherein the contact structure comprises a metal structure disposed above a contact cap layer.

7. The multifinger III-Nitride transistor device of claim 6, wherein the barrier layer is removed beneath the contact cap layer such that the contact cap layer is disposed on the channel layer.

8. The multifinger III-Nitride transistor device of claim 6, wherein electrical properties of the barrier layer or the channel layer beneath the contact cap layer are modified such that carriers are not present in the channel layer beneath the contact structure.

9. The multifinger III-Nitride transistor device of claim 1, wherein the cap contact bus comprises a metal trace disposed above a bus cap layer.

10. A multifinger III-Nitride transistor device, comprising:
a plurality of unit cells; wherein each unit cell has an active region, two ends and two sides, wherein each unit cell comprises:
a channel layer;
a barrier layer disposed on the channel layer, wherein electrons are formed at an interface between the channel layer and the barrier layer in the active region;
a plurality of source contacts disposed above the channel layer, wherein the source contacts extend across the active region from one side to an opposite side;
a plurality of drain contacts disposed above the channel layer, extending across the active region and parallel to the source contacts;
a plurality of gate regions disposed between each adjacent source contact and drain contact;
a cap layer disposed in each gate region;
a contact structure disposed at a first end of the unit cell;
a second contact structure disposed at a second end of the unit cell; and
a cap contact bus in electrical communication with the contact structure, the second contact structure, and with each of the cap layers, disposed along a first side of the unit cell;
wherein the second contact structure of a first unit cell is adjacent to the contact structure of a second unit cell and is electrically coupled together and to a common gate signal, and wherein the plurality of source contacts in each unit cell are electrically coupled to a common source signal and the plurality of drain contacts in each unit cell are electrically coupled to a common drain signal.

11. The multifinger III-Nitride transistor device of claim 10, further comprising a second cap contact bus disposed along a second side of each unit cell and in electrical communication with the contact structure, the second contact structure, and with each of the cap layers in the unit cell.

12. The multifinger III-Nitride transistor device of claim 10, wherein the plurality of unit cells each have a same configuration.

13. The multifinger III-Nitride transistor device of claim 10, wherein at least one of the plurality of unit cells has a configuration different than another of the plurality of unit cells.

14. A multifinger III-Nitride transistor device, having an active region and two ends and two sides, the multifinger III-Nitride transistor device comprising:
a channel layer;
a barrier layer disposed on the channel layer, wherein electrons are formed at an interface between the channel layer and the barrier layer in the active region;
a plurality of source contacts disposed above the channel layer, wherein the source contacts extend across the active region from one side to an opposite side;
a plurality of drain contacts disposed above the channel layer, extending across the active region and parallel to the source contacts;
a plurality of gate regions disposed between each adjacent source contact and drain contact;
a cap layer from a first set of cap layers disposed in each gate region;
a cap layer from a second set of cap layers disposed in each gate region;
a first contact structure disposed at a first end of the multifinger III-Nitride transistor device;
a second contact structure disposed at an end of the device;
a first cap contact bus in electrical communication with the first contact structure and with the first set of cap layers, disposed along a first side of the device; and
a second cap contact bus in electrical communication with the second contact structure and with the second set of cap layers, disposed along a second side of the device.

15. The multifinger III-Nitride transistor device of claim 14, further comprising a third contact structure disposed at a second end of the multifinger III-Nitride transistor device in electrical communication with the first cap contact bus.

16. The multifinger III-Nitride transistor device of claim 14, wherein the second contact structure is disposed at the first end of the multifinger III-Nitride transistor device.

17. The multifinger III-Nitride transistor device of claim 16, further comprising a third contact structure disposed at a second end of the multifinger III-Nitride transistor device in electrical communication with the first cap contact bus and a fourth contact structure disposed at the second end of the multifinger III-Nitride transistor device in electrical communication with the second cap contact bus.
